(19) United States
(12) Patent Application Publication
(10) Pub. No.: US 2019/0165818 A1
(43) Pub. Date: May 30, 2019

(54) DECODER, DECODING METHOD, AND COMMUNICATION SYSTEM

(71) Applicant: FUJITSU LIMITED, Kawasaki-shi (JP)

(72) Inventor: Shunji Miyazaki, Kawasaki (JP)

(73) Assignee: FUJITSU LIMITED, Kawasaki-shi (JP)

(21) Appl. No.: 16/175,498

(22) Filed: Oct. 30, 2018

(30) Foreign Application Priority Data
Nov. 30, 2017 (JP) 2017-231163

(51) Int. Cl. H03M 13/39; H03M 13/13; H04L 1/00

(52) U.S. Cl. CPC H03M 13/3961; H04L 1/0045; H04L 1/0041; H03M 13/13

(57) ABSTRACT

A decoder decodes an information bit sequence from a code sequence encoded by a polar code by using a successive cancellation list decoding method. The decoder includes a processor and a memory connected to the processor. The processor executes a process including configuring, to an independent value, a value of a parameter for limiting number of path candidates to sequentially identify candidates for an information bit sequence, for each position of an information bit in the information bit sequence or for each branch of an upper information bit to which a plurality of branches in a lower information bit is added.

### CROSS-REFERENCE TO RELATED APPLICATION

This application is based upon and claims the benefit of priority of the prior Japanese Patent Application No. 2017-231163, filed on Nov. 30, 2017, the entire contents of which are incorporated herein by reference.

### FIELD

The embodiments discussed herein are related to a decoder, a decoding method, and a communication system.

### BACKGROUND

In recent years, attention has been paid to polar codes that can achieve characteristics close to the Shannon limit by using channel polarization. The polar codes are also adopted as error correcting codes for control channels in fifth-generation radio communication. For decoding a polar code, a successive cancellation decoding method (hereinafter referred to as SC decoding method) is known.

The SC decoding method is a decoding method having a property of achieving the Shannon limit asymptotically, for a sufficiently long information bit length. However, there is a problem that the SC decoding method has poor characteristics for codes of small size to medium size which are usually used. This is because information bits are successively determined and fed back, and once an error occurs, that error propagates to estimation processing in a subsequent step.

Therefore, successive cancellation list decoding method (hereinafter referred to as an SCL decoding method) with improved characteristics relative to those of the SC decoding method has been devised. In the SCL decoding method, instead of narrowing down path candidates to the last one, SC operation is always performed on sequences (referred to as “paths” when imaging a tree) of candidates while holding maximum specified L path candidates. When the SCL decoding is performed at the last bit, a path associated with a high likelihood is selected.

Prior art examples are disclosed in U.S. Pat. No. 9,503,126, I. Tal and A. Vardy, “List decoding of polar codes,” in Proc. IEEE Int. Symp. Inform. Theory, St. Petersburg, Russia, July-August 2011, pp. 1-5, and C. Xiong, J. Lin, and Z. Yan, “Symbol-decision successive cancellation list decoder for polar codes,” IEEE Trans. Signal Process., vol. 64, no. 3,pp. 675-687, February 2016.

Meanwhile, in order to achieve the processing of the SCL decoding method in a reception device, further reduction in processing time and further reduction in processing amount while maintaining the characteristics have been demanded.

### SUMMARY

According to an aspect of an embodiment, a decoder for decoding an information bit sequence from a code sequence encoded by a polar code by using a successive cancellation list decoding method, the decoder includes a processor and a memory connected to the processor. The processor executes a process including configuring a value of a parameter that limits number of path candidates to sequentially identify candidates for the information bit sequence, to an independent value, for each position of an information bit in the information bit sequence or for each branch of an upper information bit to which a plurality of branches in a lower information bit is added.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating an example of polar coding;

FIG. 2 is a diagram illustrating an example of processing blocks in an SC decoding method;

FIG. 3 is a diagram illustrating an example of processing in an SC decoding method;

FIG. 4 is a diagram illustrating an example of arithmetic processing of an SC decoding method where N=8;

FIG. 5 is a diagram illustrating an example of a basic processing unit;

FIG. 6 is a diagram illustrating an example of a communication system;

FIG. 7 is a diagram illustrating an example of a path candidate selection tree according to a first embodiment;

FIG. 8 is a diagram illustrating an example of a decoder according to the first embodiment;

FIG. 9 is a block diagram illustrating an example of each SC decoder according to the first embodiment;

FIG. 10 is a flowchart illustrating an example of the operation of the decoder according to the first embodiment;

FIG. 11 is a diagram illustrating an example of a path candidate selection tree according to a second embodiment;

FIG. 12 is a diagram illustrating an example of a decoder according to the second embodiment;

FIG. 13 is a block diagram illustrating an example of each SC decoder according to the second embodiment;

FIG. 14 is a flowchart illustrating an example of the operation of the decoder according to the second embodiment;

FIG. 15 is a diagram illustrating an example of a path candidate selection tree according to a third embodiment;

FIG. 16 is a diagram illustrating an example of a decoder according to the third embodiment;

FIG. 17 is a block diagram illustrating an example of each multibit SC decoder according to the third embodiment;

FIG. 18 is a flowchart illustrating an example of the operation of the decoder according to the third embodiment;

FIG. 19 is a diagram illustrating an example of a penalty table according to a fourth embodiment;

FIG. 20 is a flowchart illustrating an example of the operation of a decoder according to the fourth embodiment; and

FIG. 21 is a diagram illustrating an example of hardware of a decoder.

### DESCRIPTION OF EMBODIMENTS

Preferred embodiments of the present invention will be explained with reference to accompanying drawings. The following embodiments do not limit the disclosed technology. In addition, the respective embodiments can be appropriately combined without inconsistency in processing contents.

Assumptions

Firstly, prior to the explanation of the embodiments, assumptions will be described.

### Encoding

A polar code is a linear block code with an information length K and a code length N. The polar code may be referred to as an (N, K) linear block code. In this case, N>K.

### [Definition]

1) Parameters:

Code length: N=2ⁿ

Information length: K

Index indicating the position of each bit in an information bit sequence: i∈A
2) Information bit sequence including a frozen bit: u=u₁^{N} [symbol] (u₁, d₂, . . . , d_{N})
3) Encoded bit sequence: x=x₁^{N} [symbol] (x₁, x₂, . . . , x_{N})
4) Unit generator matrix:

$$F = [ \begin{matrix}1 & 0 \\ 1 & 1\end{matrix} ]$$

5) Generator matrix:

$$G = {F}^{⊗ n} = \overbrace{F ⊗ F ⊗ … ⊗ F}^{n}$$

6) Kronecker product \textcircled{×}:

$$F ⊗ F = [ \begin{matrix}F & 0 \\ F & F\end{matrix} ]$$

7) 2-bit vector: u(i₁, u₂)=(uᵢ_{₁}, uᵢ_{₂})

### [Principle of Encoding]

(1) An information bit sequence into which a frozen bit is inserted is defined as an information-frozen bit sequence u.

Information bit: i∈A

Frozen bit: i∈A

In the present specification, frozen bit uᵢ=0.
(2) The generator matrix is caused to act from the right.

x=uG

Basic code framework

[symbol]

[symbol]

The polar code being a linear block code having an information length K and a code length N is defined by a generator matrix G_{I} of size K×N, and the polar coding is performed by using the following matrix operation.

x=u_{I}G_{I}

Here, u_{I} [symbol] (u₁, u₂, . . . , u_{K}) is an information bit sequence, and x [symbol] (x₁, x₂, . . . , x_{N}) is an encoded bit sequence.

As expressed below, the polar code is expressed by an extended generator matrix G and an extended information bit sequence u. The generator matrix G has an extended size N×N including, as row vectors, all row vectors constituting G_{I} having a generalized expression form of the polar code (normally referred to as a “coset code” form).

x=uG

Here, u is a sequence in which an information bit sequence u_{I} is inserted to positions of elements corresponding to rows added in G to be a sequence in which fixed bits known between a transmitter and a receiver are inserted. Such known fixed bits are called “frozen bit”.

Polar Code

A polar code is defined in the following two points.

(1) A coset code, and its generator matrix G is configured as follows assuming that a Kronecker product (direct product) is repeatedly applied with a generator matrix F for 2 bits as a basic element.

G=F^{\textcircled{×}n}

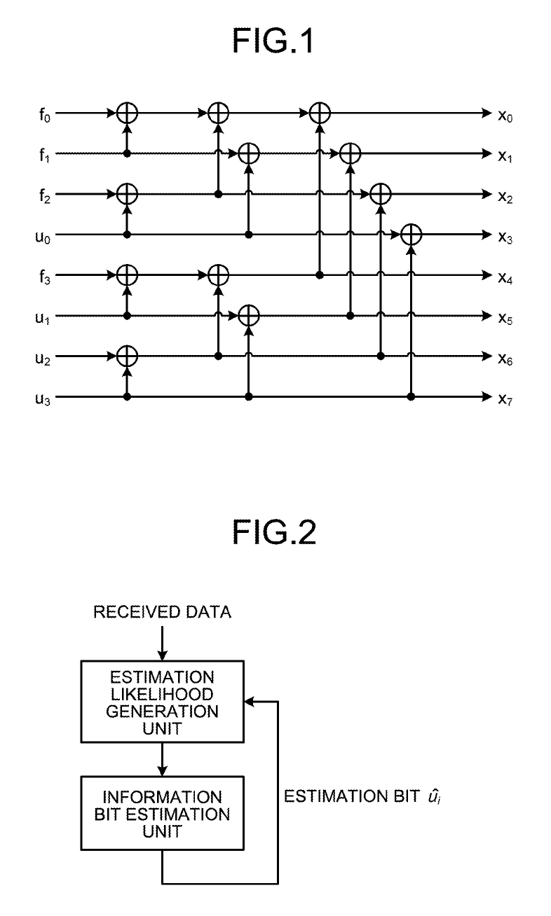

(2) Positions of information bits in an information bit sequence are selected in descending order of capacity, with a capacity for each bit as a selection index. Bits (“frozen bits”) known between transmission and reception are allocated to the remaining N−K positions. That is, a bit with a small index value is allocated to a channel with a poor quality, and a bit with a large index value is allocated to a channel with a good quality. FIG. 1 is a diagram illustrating an example of polar coding.

2. Decoding Processing

2.1 SC Decoding

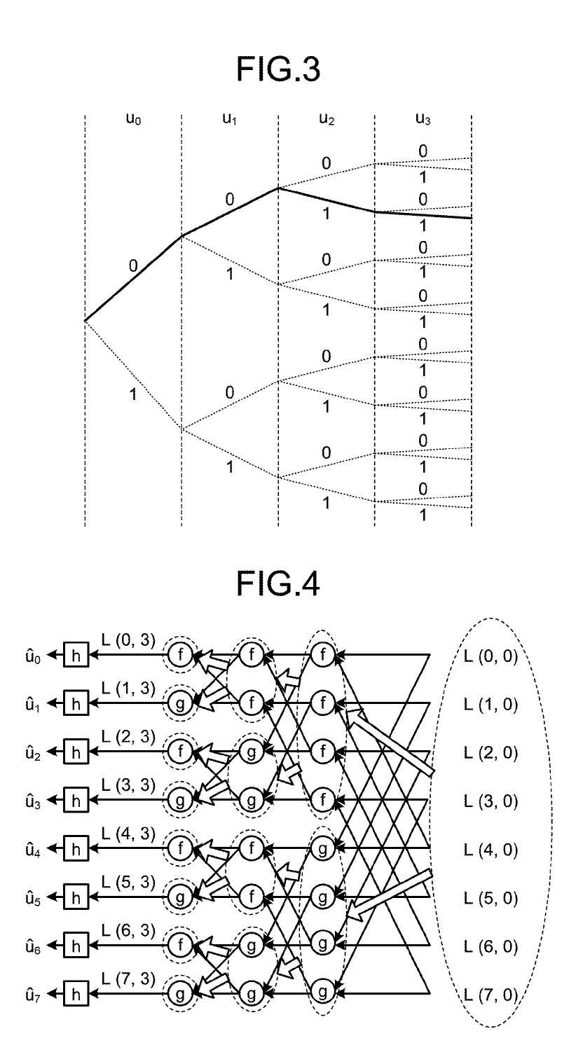

FIG. 2 is a diagram illustrating an example of processing blocks in an SC decoding method. FIG. 3 is a diagram for explaining an example of processing in an SC decoding method. In the SC decoding method, information bits included in an information bit sequence are successively estimated one bit at a time on the basis of a likelihood value (soft decision data) in ascending order (in an order of increasing index i). However, the likelihood of each information bit is calculated and determined in a form in which bit estimation results up to a corresponding bit are fed back, taking the value into consideration. Every time a bit value is fixed, path candidates of a tree are limited, and the other path candidates are “canceled”. Therefore, this method is called successive cancellation.

2.2 Detailed Description

FIG. 4 is a diagram illustrating an example of arithmetic processing of an SC decoding method for N=8. A log likelihood ratio L (i, 0) is obtained from a received data sequence y=(y₁, y₂, . . . , y_{N}). There are several different ways of expressing likelihood. In the present specification, a log likelihood ratio is used as an example of likelihood. However, an expression method of the likelihood is not limited to a specific expression.

In FIG. 4, the log-likelihood ratio L (i, 0) is input from the right. In FIG. 4, f and g each represent a node of an arithmetic unit, and a line connecting the nodes indicates a data transfer relationship. Symbols f and g each represent a function executed in an arithmetic unit. A node group surrounded by a dotted line means that calculation of a similar function that is performed simultaneously in arithmetic units in an identical column (hereinafter referred to as “stage”).

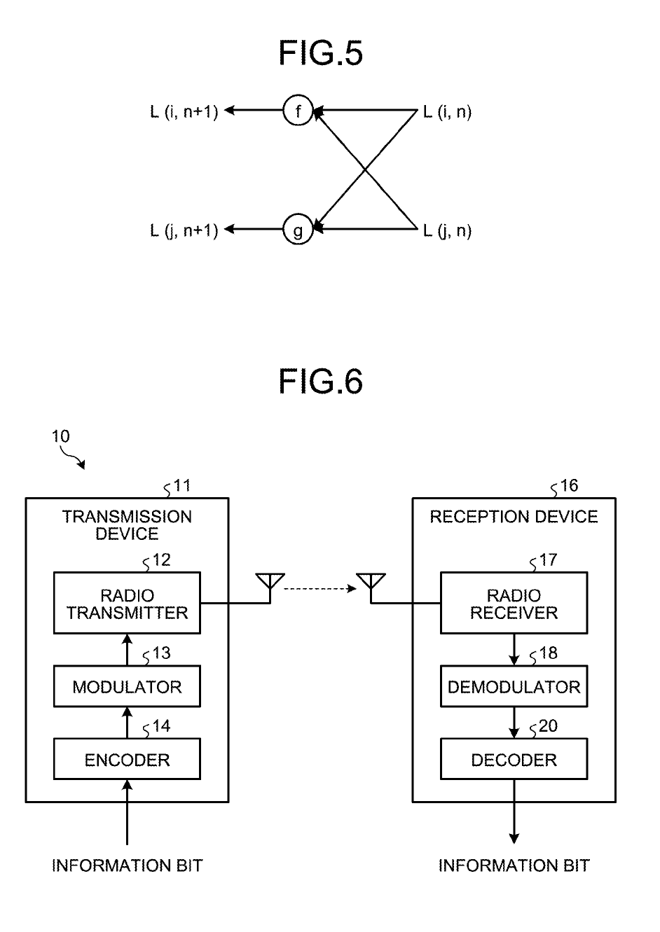

Each step corresponds to inverse calculation to each unit calculation operation in the encoding of FIG. 1. Each step has unit processing configured so that two pieces of likelihood data of outputs from a previous stage are input to each pair of f- and g-nodes, and the results of calculation thereof are input to a next step. FIG. 5 is a diagram illustrating an example of a basic processing unit. Here, g-operation is a calculation operation dependent on information bits estimated so far. For a bit to be fed back, an estimation bit is input. The estimation bit corresponds to an encoded bit at an intermediate step in a corresponding stage in an encoding process. This can be obtained by re-encoding information bits estimated before this operation is performed. When this unit calculation is executed up to the last stage (leftmost side), an estimation bit is obtained by taking hard decisions represented by h, on the basis of output likelihoods.

The mathematical expression of the above algorithm is summarized as follows.

### [Definition]

1) Received data sequence: y=y₁^{N} [symbol] (y₁, y₂, . . . , y_{N})
2) Channel transition probability for each bit: W(yᵢ|uᵢ)
3) Transition probability of Polar-encoded channel: W(y,û₁ⁱ⁻¹|uᵢ)
4) Log likelihood ratio:

$$LLR [ y , {\hat{u}}_{1}^{i - 1} ] {=}^{Δ} ln ( \frac{W ( y , {\hat{u}}_{1}^{i - 1} \vert {u}_{i} = 0 )}{W ( y , {\hat{u}}_{1}^{i - 1} \vert {u}_{i} = 1 )} )$$

5) Log likelihood ratio in j-stage: L(i,j)

Input (initialization):

$$L ( i , 0 ) = ln ( \frac{W ( {y}_{i} \vert {u}_{i} = 0 )}{W ( {y}_{i} \vert {u}_{i} = 1 )} )$$

Output: L(i,n)=LLR[y,û₁ⁱ⁻¹]
6) Estimated information (frozen) bit sequence:

û=û₁^{N} [symbol] (û₁, û₂, . . . , û_{N})
7) Arithmetic node

### <Overview>

In arithmetic processing illustrated in FIG. 4, arithmetic node corresponds to intermediate calculation of element encoding for each bit.

A 2-bit input having a smaller index is referred to as “f node” and one having a larger index is referred to as “g node”.

### <Detailed Definition>

Arithmetic node is expressed using indices (s, k, l) introduced in the encoding described in the previous section.

In the following likelihood updating formula, (i_{g}, i_{f}) corresponds to an index i in each node used in the likelihood updating formula.

For log likelihood calculation in a stage n−s=j|1,

f node: index i_{f}=2^{g}2k+l=i_{g}−N/2ⁱ⁺¹ 7-1)

f node: index i_{g}=2^{s}2k+2^{s}+l=i_{f}−N/2^{j+1} 7-2)

Here, k=0,1, . . . ,N/2^{s+1}=2^{j}, l=0,1, . . . , 2^{s}−1=N/2^{j+1}−1

2^{s}=2^{n-j-1}=N/2^{j+1}

### [Summary of Procedure]

### <Input Data>

(1) Estimation is started sequentially from the first bit of an information-frozen bit sequence u.
(2) An estimation bit is determined using a hard decision on the log likelihood ratio LLR[y,ûⁱ⁻¹ ] successively determined for each bit.
(i) Information bit: i∈A

$${}_{i} = h ( LLR [ y , {\hat{u}}_{1}^{i - 1} ] ) = \{ \begin{matrix}0 , & LLR [ y , {\hat{u}}_{1}^{i - 1} ] \geq 0 \\ 1 , & LLR [ y , {\hat{u}}_{1}^{i - 1} ] < 0\end{matrix}$$

(ii) Frozen bit: i∈A

ûᵢ=0
(3) Likelihood for estimation of the i-th bit W(y,û₁ⁱ⁻¹⊕uᵢ) (hereinafter, referred to as “estimation likelihood”) is determined based on an estimation bit not more than an (i−1)-th bit. Accordingly, the likelihood is successively determined from the first bit.
(4) Estimation likelihood is determined from received likelihood using successive “stage calculation”.

For stage j+1(=n−s),j=0,1, . . . ,n−1

$$L ( i , j + 1 ) = \{ \begin{matrix}f ( L ( i , j ) , L ( i + N / {2}^{j + 1} , j ) ) & for f node \\ g ( L ( i - N / {2}^{j + 1} , j ) , L ( i , j ) , {\hat{u}}_{sum} ) & for g node\end{matrix}$$

Here, ûₛᵤₘ represents an information bit in the j+1 (a sum in an f node to an input encoded bit in a stage j).
(5) Logical formula

$$f ( a , b ) = 2 {tanh}^{- 1} ( tanh ( a / 2 ) tanh ( b / 2 ) ) = ln ( \frac{1 + {e}^{a + b}}{{e}^{a} + {e}^{b}} ) \\ g ( a , b , {\hat{u}}_{sum} ) = {a ( - 1 )}^{{\hat{u}}_{sum}} + b$$

(6) Min-sum approximation

f(a,b)≈sgn(a)sgn(b)min(|a|,|b|)

g(a,b,ûₛᵤₘ)=a(−1)^{û}^{ₛᵤₘ}+b

### [a] First Embodiment

FIG. 6 is a diagram illustrating an example of a communication system 10. The communication system 10 includes a transmission device 11 and a reception device 16. The transmission device 11 includes a radio transmitter 12, a modulator 13, and an encoder 14. The encoder 14 generates an encoded bit sequence by encoding input information bits, for example, by using a coding method illustrated in FIG. 1. Then, the encoder 14 outputs the generated encoded bit sequence to the modulator 13. The modulator 13 modulates the encoded bit sequence output from the encoder 14 and outputs the bit sequence to the radio transmitter 12. The radio transmitter 12 converts the encoded bit sequence modulated by the modulator 13 into a radio signal and radiates the radio signal in air via an antenna. The communication system 10 according to the present embodiment includes the transmission device 11 and the reception device 16 that perform wireless communication, but the transmission device 11 and the reception device 16 may be devices that perform wired communication as long as the devices have a system for communication.

The reception device 16 includes a radio receiver 17, a demodulator 18, and a decoder 20. The radio receiver 17 receives the wireless signal transmitted from the transmission device 11 via an antenna, converts the received signal into an electric signal, and outputs the electric signal to the demodulator 18. The demodulator 18 demodulates the signal output from the radio receiver 17 and outputs the demodulated signal to the decoder 20 together with a channel likelihood. In the present embodiment, the channel likelihood is, for example, a log-likelihood ratio (LLR). The decoder 20 decodes an information bit by using an SCL decoding method, on the basis of the demodulated signal and the channel LLR output from the demodulator 18. Then, the decoder 20 outputs the decoded information bit to a processing block that performs predetermined processing by using the information bit.

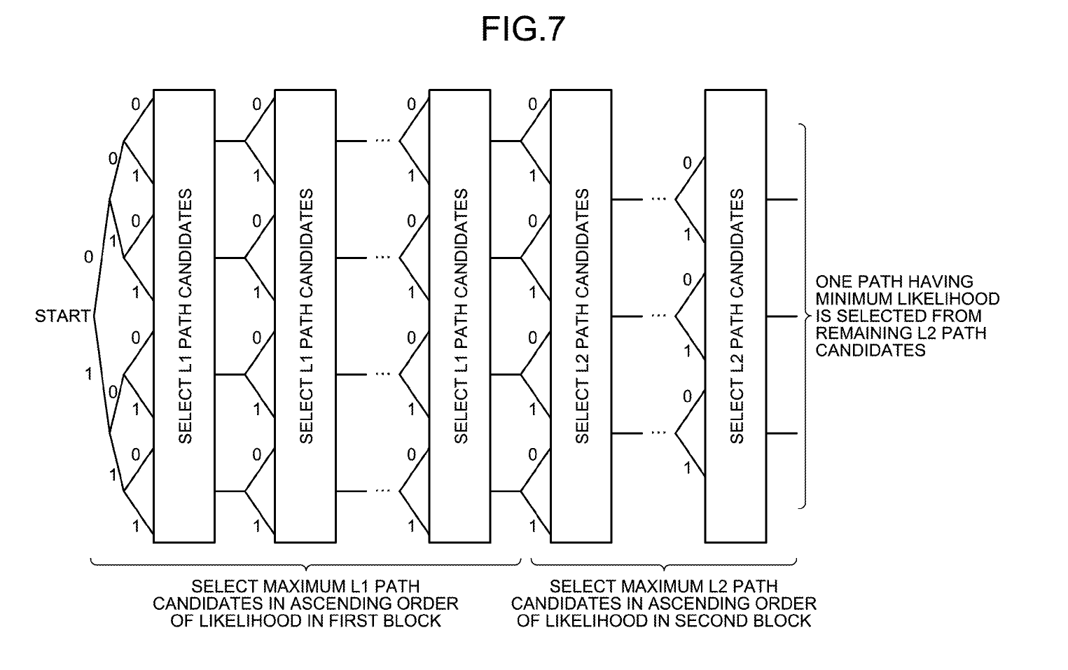

FIG. 7 is a diagram illustrating an example of a path candidate selection tree according to the first embodiment. The decoder 20 according to the present embodiment divides an information bit sequence into a plurality of blocks each including at least one information bit. Then, the decoder 20 sets the value of list number L used in the SCL decoding to independent values for the respective blocks. When the number of blocks is N_{b} and the size of an information bit sequence is K, a block size K_{b} is K/N_{b}. When the number N_{b} of blocks and the size K of the information bit sequence are the same, the value of the list number L is set to independent values for respective information bits. The value of the list number L is an example of the value of a parameter that limits the number of path candidates for sequentially identifying candidates for an information bit sequence.

Further, the decoder 20 according to the present embodiment sets a value of the list number L set in a block including an information bit having a larger index value to a smaller value than a value of the list number L set in a block including an information bit having a smaller index value. The index is information indicating the position of an information bit in an information bit sequence. For example, in the example of FIG. 7, the value of list number L1 used in a first block is 4 and the value of list number L2 used in a second block is 3. The first block is an example of a block including an information bit having a smaller index value and the second block is an example of a block including an information bit having a larger index value.

In the SCL decoding method, a path metric (PM) is defined, as an index for comparing the goodness between paths. For the PM according to the present embodiment, a log likelihood at each bit position may be used, as SC decoding in each sequence. In the present embodiment, the smaller the PM size, the better the path. For example, when the number of list is L1, the number of path candidates is L1, and when two candidate branches 0 and 1 are added to L1 path candidates, for the next bit, the number of path candidates becomes 2L1. From among the L1 path candidates, L1 path candidates are selected as next remaining paths in ascending order of PM. Therefore, in each selection processing, sort processing is performed on the 2L1 path candidates.

Here, the polar code has a characteristic that a latter half of an information-frozen bit sequence (bit having a larger index value) provides a better channel capacity. Therefore, even though the value of the list number L is reduced in the latter half of the information-frozen bit sequence, it is presumed that the reduction does not significantly affect the characteristic. Then, when the value of the list number L decreases, the number of path candidates decreases, and in narrowing down the path candidates, a processing amount upon sorting the path candidates on the basis of a likelihood value is reduced. Therefore, processing time of and a processing load on the decoder 20 in the SCL decoding process can be reduced.

Switching between the first block and the second block can be determined, for example, by using a value calculated by simulation in advance. For another method, a reference value may be provided for an index (for example, at least one of a signal to noise ratio (SNR), capacity, path metric, and average value of the path metric) indicating a characteristic of each bit so that the reference vales are switched according to a relationship between the reference value and the index. For example, in a case of using the average value of the path metric as the index indicating the characteristic, when the average value of the path metric is larger than the reference value for the average value of the path metric, the number of path candidates to be selected is reduced.

Decoder 20

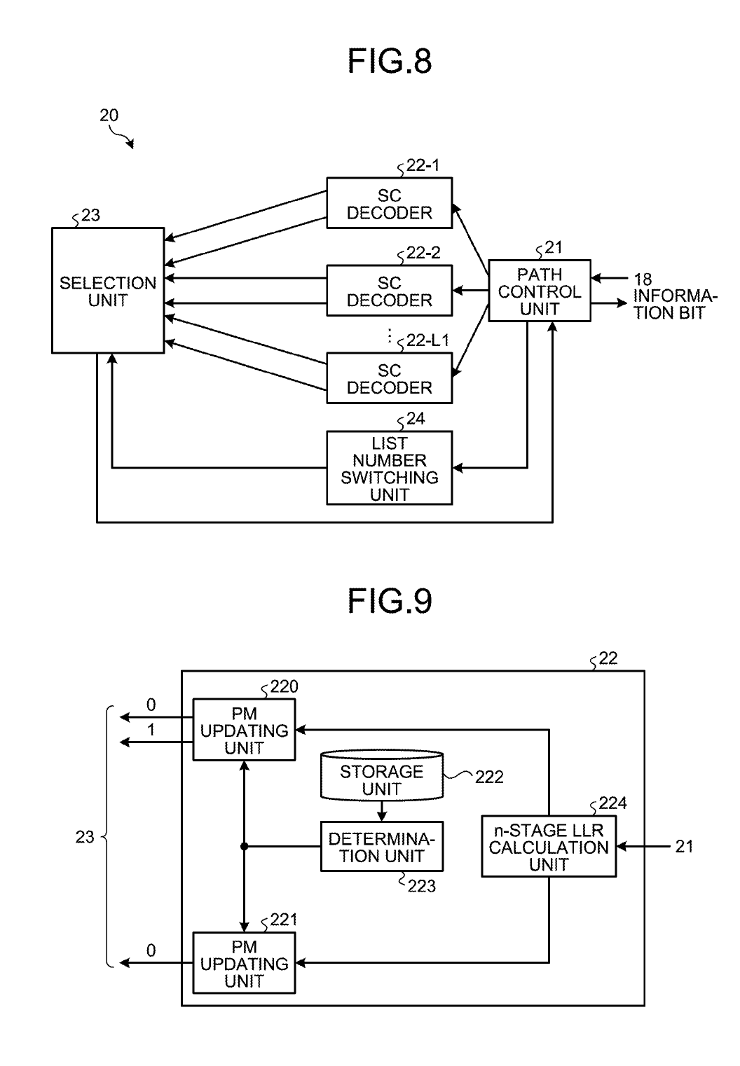

FIG. 8 is a diagram illustrating an example of the decoder 20 according to the first embodiment. The decoder 20 according to the present embodiment includes a path control unit 21, a plurality of SC decoders 22-1 to 22-L1, a selection unit 23, and a list number switching unit 24. In the following description, the SC decoders 22-1 to 22-L1 are collectively called a SC decoders 22 when the path control units are not distinguished from each other. In addition, the decoder 20 is provided with a processor and a memory, and the processor executes a program read from the memory, whereby the function of each block illustrated in FIG. 8 is achieved.

The path control unit 21 outputs a channel LLR output from the demodulator 18 and path candidates selected by the selection unit 23, to SC decoders 22. In the present embodiment, since the maximum L1 path candidates are selected, the path control unit 21 allocates path candidates selected by the selection unit 23 to L1 SC decoders 22. Further, the path control unit 21 outputs an index value of an information-frozen bit sequence to the list number switching unit 24. Further, when path candidates are selected from the last bit of the information-frozen bit sequence by the selection unit 23, the path control unit 21 identifies a path candidate having the smallest PM from the selected path candidates. Then, the path control unit 21 performs error correction processing, such as CRC, on the information-frozen bit sequence corresponding to the identified path candidate and decodes an information bit. Then, the path control unit 21 outputs the decoded information bit.

Each of the SC decoders 22 calculates an LLR of each added branch, for each path candidate. Then, each SC decoder 22 updates path candidates and PMs thereof by adding an LLR calculated for each branch to a PM of a path candidate.

When a total number of path candidates output from the respective SC decoders 22 is equal to or less than the number of lists indicated by the list number switching unit 24, the selection unit 23 outputs path candidates and PMs thereof output from the respective SC decoders 22 to the path control unit 21. In contrast, when a total number of path candidates output from the respective SC decoders 22 is larger than the number of lists indicated by the list number switching unit 24, the selection unit 23 sequentially selects path candidates, the number of which is the same as that indicated by the list number switching unit 24, in ascending order of PMs. Then, the selection unit 23 outputs the selected path candidates and PMs thereof to the path control unit 21.

On the basis of an index output from the path control unit 21, the list number switching unit 24 switches the number of lists to be indicated to the selection unit 23. In the present embodiment, the list number switching unit 24 sets the value of list number L2 set in a block including an information bit having a larger index value to a smaller value than a value of list number L1 set in a block including an information bit having a smaller index value.

SC Decoder 22

FIG. 9 is a block diagram illustrating an example of each SC decoder 22 according to the first embodiment. The SC decoder 22 according to the present embodiment includes a PM updating unit 220, a PM updating unit 221, a storage unit 222, a determination unit 223, and an n-stage LLR calculation unit 224. The n-stage LLR calculation unit 224 calculates an LLR of each branch in each stage and outputs the calculated LLR to the PM updating unit 220 and the PM updating unit 221. In the following description, a process of calculating an LLR of each branch in each stage may be referred to as an n stage LLR operation.

The storage unit 222 stores an index value of a frozen bit in an information-frozen bit sequence. The storage unit 222 may store an index value of an information bit. The determination unit 223 refers to the storage unit 222 for each index value and determines whether an index value represents an index of an information bit or an index of a frozen bit. Then, the determination unit 223 outputs a determination result to the PM updating unit 220 and the PM updating unit 221.

When it is determined that the index is an index of an information bit by the determination unit 223, the PM updating unit 220 adds a plurality of branches (the branch corresponding to “0” and the branch corresponding to “1” in the example of FIG. 9) to a path candidate. Then, for each of the added branches, the PM updating unit 220 sets a path candidate to which the branch is added as a new path candidate. Then, the PM updating unit 220 adds an LLR of the branch calculated by the n-stage LLR calculation unit 224 to PMs of the path candidates, thereby updating a PM of the new path candidate. Then, the PM updating unit 220 outputs the new path candidate and the updated PM thereof to the selection unit 23.

When it is determined that the index is an index of a frozen bit by the determination unit 223, the PM updating unit 221 adds a branch corresponding to “0” which is a value of the frozen bit to the path candidates. Then, the PM updating unit 221 sets a path candidate to which the branch is added as a new path candidate. Then, the PM updating unit 221 adds an LLR of the branch calculated by the n-stage LLR calculation unit 224 to PMs of the path candidates, thereby updating a PM of the new path candidate. Then, the PM updating unit 221 outputs the new path candidate and the updated PM thereof to the selection unit 23.

The mathematical expression of the PM and updating the PM is summarized as follows.

### [Definition]

1) List size: L
2) Path candidate of i-th bit length: an information-frozen bit sequence of an index j=1, 2, . . . , i to which any temporary bit value z₁ⁱ=(z₁, . . . , z₁)∈{0,1}ⁱ is given.
3) i-th (bit length) path metric:

$$M ( {z}_{1}^{i} ) = - ln ( Pr ( {\hat{u}}_{1}^{i} = {z}_{1}^{i} ) ) = {\sum }_{j = 0}^{i} ln ( 1 + {e}^{- ( 1 - 2 {z}_{j} ) {L}_{j}} )$$

* In the present embodiment, a “smaller” path metric represents a “better path”.
4) Log likelihood ratio of i-th (bit): Lᵢ=LLR[y,û₁ⁱ⁻¹]

### [Path Metric Update Processing]

The i-th path metric is given by using the following repetitive formulas, for each zᵢ=0,1. The repetitive formulas are obtained based on an estimation log likelihood ratio sᵢ determined by an SC decoder for a given path z₁ⁱ⁻¹.

M(zᵢ, z₁ⁱ⁻¹)=ln(1+e^{-(1-2z}^{ᵢ}^{)s}^{ᵢ})+M(z₁ⁱ⁻¹) (i) Logical formula

### (ii) Min-Sum Approximation

$$M ( {z}_{i} , {z}_{1}^{i - 1} ) = \{ \begin{matrix}M ( {z}_{1}^{i - 1} ) & if ( 1 - 2 {z}_{i} ) = sgn ( {s}_{i} ) \\ M ( {z}_{1}^{i - 1} ) + \vert {s}_{i} \vert & otherwise\end{matrix}$$

Final Path Selection Process

After selecting lists for the last bit, an optimum path is selected. Several methods are known as selection methods, but in the present embodiment, it is assumed that a selection method is performed according to a CRC aided (CA) polar method adopted in the most popular standard specification. The CRC aided polar method is a coding method by which a CRC parity bit is added to an information bit so that the CRC parity bit is incorporated in part of the information bit, before the information bit is input to the polar code. On the receiving side, CRC is performed on a bit sequence corresponding to each final remaining path in a list, and a bit sequence determined OK is selected as the final result. Furthermore, when all CRC indicate NG, a path having the best metric is selected.

Operation of Decoder 20

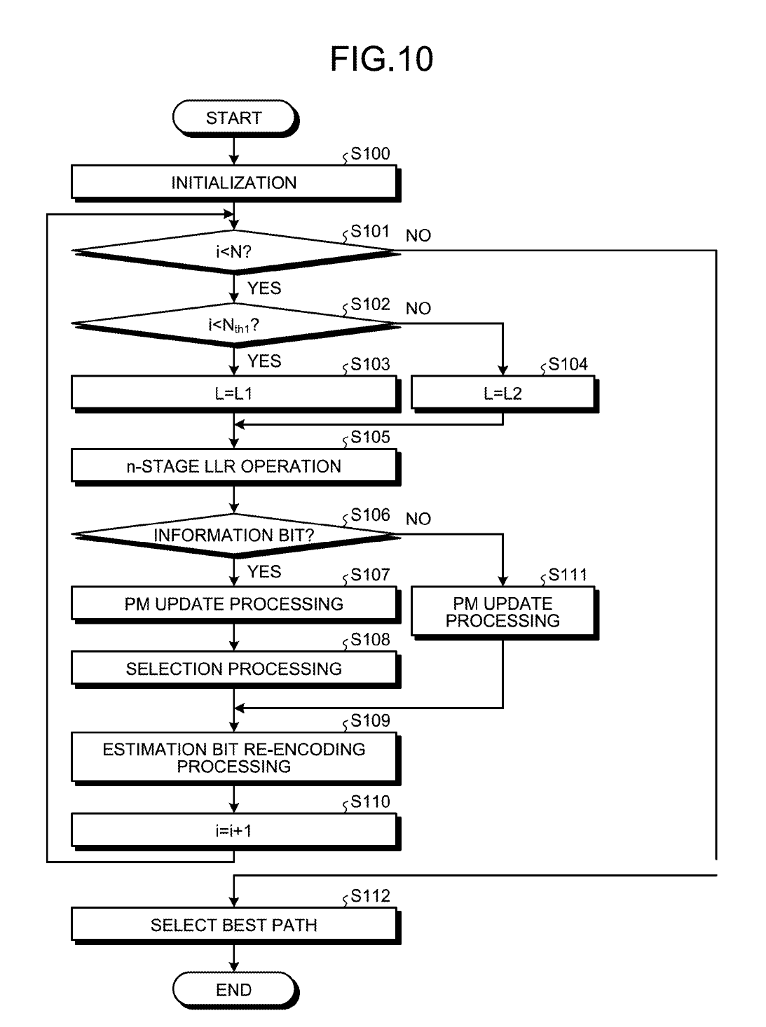

FIG. 10 is a flowchart illustrating an example of the operation of the decoder 20 according to the first embodiment. The decoder 20 starts operation of this flowchart, for example, each time a code of predetermined length N is received.

First, the decoder 20 initializes each part of the decoder 20 (S100). In Step S100, for example, the value of variable i indicating an index of an information-frozen bit sequence is initialized to zero.

Next, the path control unit 21 determines whether the value of the variable i is less than a value N of a code length (S101). When the value of variable i is less than the value N (S101: Yes), the list number switching unit 24 determines whether the value of variable i is less than a value Nₜₕ₁ corresponding to boundaries between blocks (S102). When the value of variable i is less than the value Nₜₕ₁ (S102: Yes), the list number switching unit 24 instructs the selection unit 23 to set L1 as the list number L (S103). In contrast, when the value of variable i is equal to or larger than the value Nₜₕ₁ (S102: No), the list number switching unit 24 instructs the selection unit 23 to set L2 as the list number L (S104).

Next, the n-stage LLR calculation unit 224 in each SC decoder 22 executes n-stage LLR operation (S105). Then, the determination unit 223 refers to the storage unit 222 and determines whether a bit having an index corresponding to the variable i is an information bit (S106). When the bit having an index corresponding to the variable i is the information bit (S106: Yes), the PM updating unit 220 adds a plurality of branches corresponding to a lower information bit to a path candidate corresponding to an upper information bit, and for each of the added branches, a path candidate to which each branch is added is set as a new path candidate. Then, the PM updating unit 220 adds an LLR of the branch calculated by the n-stage LLR calculation unit 224 to a PM of the path candidate, thereby updating a PM of the new path candidate (S107).

Next, the selection unit 23 selects the maximum L path candidates from path candidates output from the SC decoders 22 in ascending order of PM values (S108). Then, the path control unit 21 executes re-encoding processing of an estimation bit on the basis of the path candidates selected by the selection unit 23 (S109). Then, the path control unit 21 increases the variable i by 1 (S110) and performs the processing of Step S101 again.

In Step S106, when the bit having an index corresponding to the variable i is a frozen bit (S106: No), the PM updating unit 221 adds a branch corresponding to “0” which is the value of the frozen bit, to the path candidate. Then, the PM updating unit 221 sets a path candidate to which the branch is added as a new path candidate. Then, the PM updating unit 221 adds an LLR of the branch of the frozen bit calculated by the n-stage LLR calculation unit 224 to a PM of the path candidate, thereby updating a PM of the new path candidate (S111). Then, the processing of Step S109 is performed.

In Step S101, when the value of the variable i is not less than the value N of the code length (S101: No), the path control unit 21 selects a path candidate having the smallest PM from the path candidates selected by the selection unit 23 to select the best path (S112). Then, the path control unit 21 performs error correction processing, such as CRC, on an information-frozen bit sequence corresponding to the selected path and decodes an information bit. Then, the path control unit 21 outputs the decoded information bit.

### Effects of First Embodiment

The first embodiment has been described above. The decoder 20 according to the present embodiment is a decoder for decoding an information bit sequence from a code sequence encoded by the polar code by using the SCL decoding method, and the decoder 20 includes a processor and a memory connected to the processor. The processor sets, to independent values, the value of the list number L for limiting the number of path candidates to sequentially identify candidates for an information bit sequence, for each information bit position in an information bit sequence. Therefore, the decoder 20 reduces the time and amount of processing of the SCL decoding method.

Further, in the present embodiment, the processor of the decoder 20 divides an information bit sequence into a plurality of blocks including at least one information bit, and sets values of the list number L used to sequentially identify the information bit sequence candidates to independent values for the respective blocks. Therefore, the decoder 20 reduces the time and amount of processing of the SCL decoding method.

Further, in the present embodiment, the processor of the decoder 20 sets a value of the list number L set in a block including an information bit having a larger index value to a smaller value than a value of the list number L set in a block including an information bit having a smaller index value, in an information bit sequence. Therefore, the decoder 20 reduces the time and amount of processing of the SCL decoding method.

### [b] Second Embodiment

In the first embodiment, the list number L, which is a parameter for limiting the number of path candidates, is set smaller for a bit having a larger index. In contrast, in the second embodiment, for each of bits of indexes having a value not more than a predetermined value, branches corresponding to the value of a bit is added to path candidates, thereby updating the path candidates. For each of bits having indexes more than the predetermined value, branches corresponding to the value of a bit selected from path candidates by a hard decision is added. In this way, in the present embodiment, the number of branches corresponding to a lower information bit, which are added to path candidates corresponding to an upper information bit, is set to independent values for predetermined indexes. Therefore, the number of path candidates does not increase for bits after an index having a value larger than the predetermined index, and the process of narrowing down the number of path candidates to the list number L in ascending order of PM can be omitted. Therefore, it is possible to reduce the time and amount of processing of the SCL decoding method.

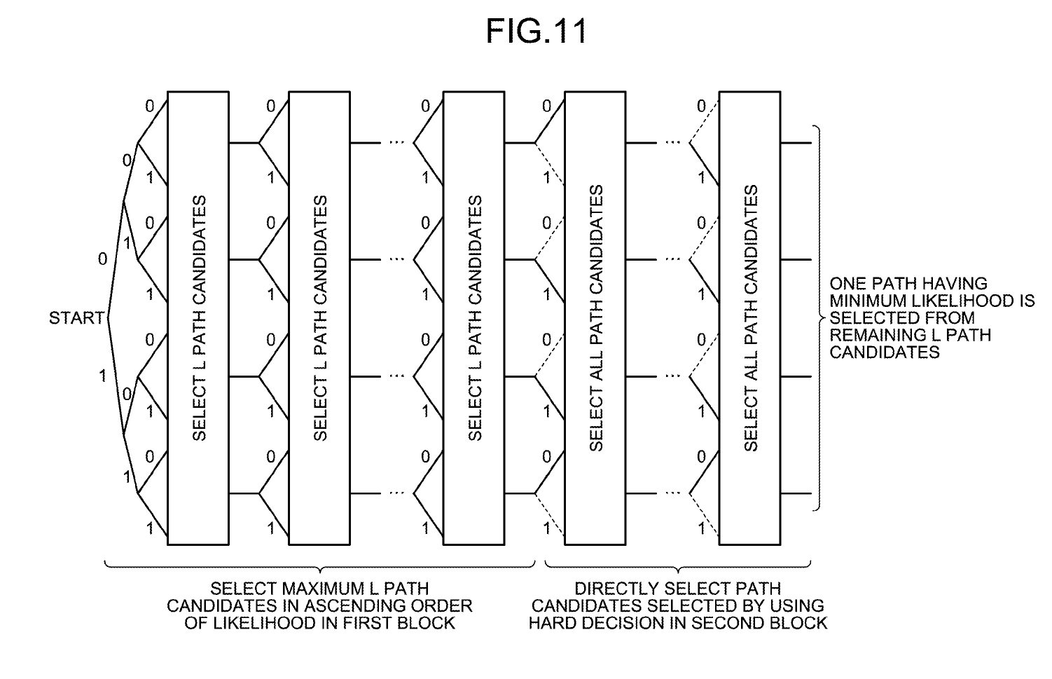

FIG. 11 is a diagram illustrating an example of a path candidate selection tree according to the second embodiment. The decoder 20 according to the present embodiment divides an information bit sequence into two blocks each including at least one information bit. In a first block corresponding to an index indicating a first half position, the decoder 20 updates path candidates by adding branches corresponding to the value of a bit to path candidates, and narrows down the number of path candidates to the list number L in ascending order of PM.

In contrast, in a second block corresponding to an index indicating a second half position, only branches corresponding to the value of a bit selected by the hard decision in path candidates are added. Therefore, in the second block, the number of path candidates is less than or equal to the list number L, and the process of narrowing down the number of path candidates to the list number L in ascending order of PM can be eliminated. In the second block of FIG. 11, a branch indicated by a dotted line represents a branch not selected as a result of the hard decision.

Switching between the first block and the second block can be determined, for example, by using a value calculated by simulation in advance. Furthermore, for another method, a reference value may be provided for an index (for example, at least one of an SNR, capacity, path metric, and average value of the path metric) indicating a characteristic of each bit so that the reference vales are switched according to a relationship between the reference value and the index. For example, in a case of using the average value of the path metric as the index indicating the characteristic, when the average value of the path metric is larger than the reference value for the average value of the path metric, the number of path candidates to be selected is reduced.

Decoder 20

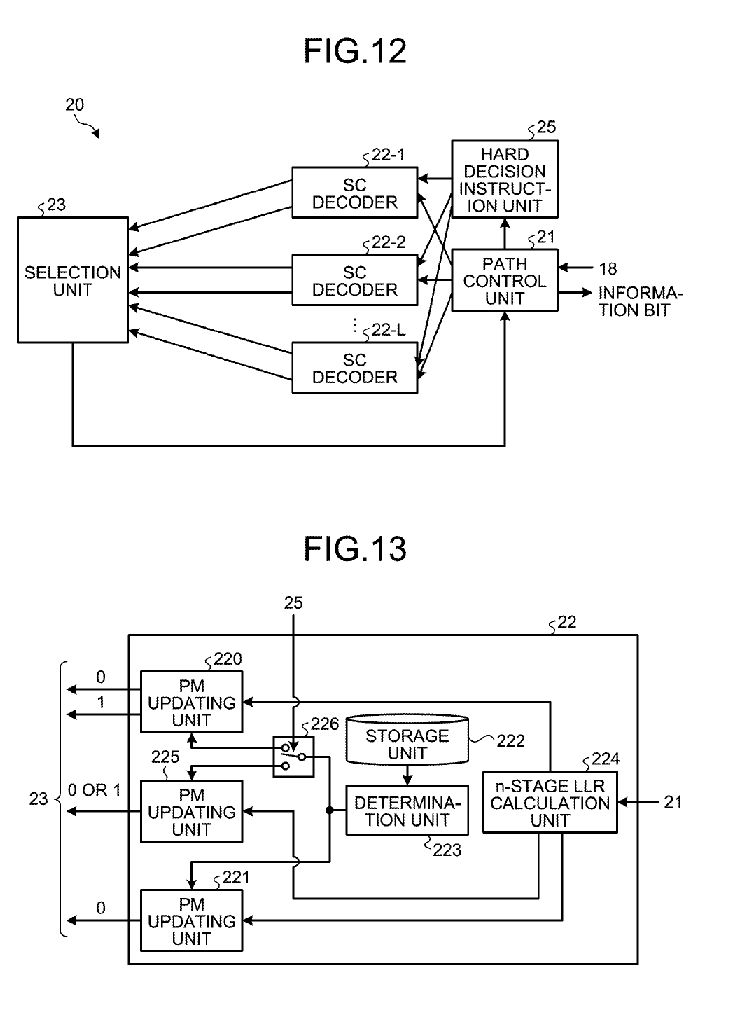

FIG. 12 is a diagram illustrating an example of a decoder 20 according to the second embodiment. The decoder 20 according to the present embodiment includes a path control unit 21, a plurality of SC decoders 22-1 to 22-L, a selection unit 23, and a hard-decision instruction unit 25. In FIG. 12, blocks denoted by the same reference numerals as those of the blocks illustrated in FIG. 8 are the same as the blocks illustrated in FIG. 8, except for the points described below, and duplicate descriptions are omitted.

The decoder 20 according to the present embodiment has L SC decoders 22. On the basis of an index output from the path control unit 21, the hard-decision instruction unit 25 instructs each SC decoder 22 to perform hard decision. For example, when an index value becomes equal to or larger than a predetermined value, the hard-decision instruction unit 25 instructs each SC decoder 22 to perform hard decision.

SC Decoder 22

FIG. 13 is a block diagram illustrating an example of each SC decoder 22 according to the second embodiment. The SC decoder 22 according to the present embodiment includes a PM updating unit 220, a PM updating unit 221, a storage unit 222, a determination unit 223, an n-stage LLR calculation unit 224, a PM updating unit 225, and a switch 226. In FIG. 13, blocks denoted by the same reference numerals as those of the blocks illustrated in FIG. 9 are the same as the blocks illustrated in FIG. 9, except for the points described below, and duplicate descriptions are omitted.

When no instruction on the hard decision is given from the hard-decision instruction unit 25, the switch 226 outputs a result of determination performed by the determination unit 223 to the PM updating unit 220. When instructions on the hard decision are given from the hard-decision instruction unit 25, the switch 226 outputs a result of determination performed by the determination unit 223 to the PM updating unit 225.

When it is determined that an index value is an index of an information bit by the determination unit 223, the PM updating unit 225 compares LLRs of a plurality of branches to be added to a path candidate. Then, the PM updating unit 225 creates a new path candidate by adding a branch corresponding to a lower LLR to path candidates. Then, the PM updating unit 225 adds an LLR of the added branch to a PM of the path candidate, thereby updating a PM of the new path candidate. Then, the PM updating unit 225 outputs the new path candidate and the updated PM thereof to the selection unit 23.

Operation of SC Decoder 22

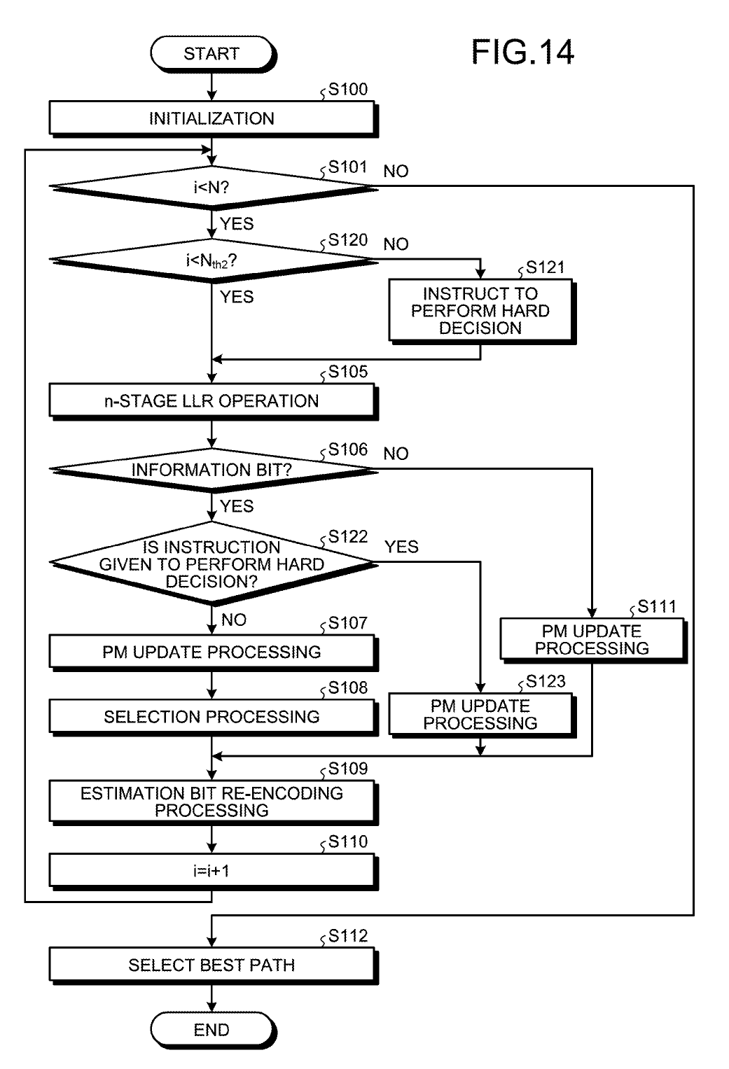

FIG. 14 is a flowchart illustrating an example of the operation of the decoder 20 according to the second embodiment. In FIG. 14, processing denoted by the same reference numerals as those of the processing illustrated in FIG. 10 is the same as the processing illustrated in FIG. 10, except for the points described below, and duplicate explanations are omitted.

When the value of variable i is less than the value N (S101: Yes), the hard-decision instruction unit 25 determines whether the value of variable i is less than a value Nₜₕ₂ corresponding to boundaries between blocks (S120). When the value of variable i is less than the value Nₜₕ₂ (S120: Yes), the processing of Step S105 is performed. In contrast, when the value of the variable i is equal to or larger than the value Nₜₕ₂ (S120: No), the hard-decision instruction unit 25 instructs each SC decoder 22 to perform hard decision (S121).

When a bit having an index corresponding to the variable i is an information bit (S106: Yes), the switch 226 determines whether instructions on the hard decision are given from the hard-decision instruction unit 25 (S122). When no instruction on the hard decision is given from the hard-decision instruction unit 25 (S122: No), the switch 226 outputs a result of determination performed by the determination unit 223 to the PM updating unit 220. Then, the processing of Step S107 is performed.

In contrast, when instructions on the hard decision are given from the hard-decision instruction unit 25 (S122: Yes), the switch 226 outputs a result of determination performed by the determination unit 223 to the PM updating unit 225. The PM updating unit 225 performs PM update processing (S123). In Step S123, LLRs of a plurality of branches to be added to a path candidate are compared, and a branch corresponding to a lower LLR is added to the path candidate, and a new path candidate is created. Then, by adding the LLR of the added branch to PMs of the path candidates, a PM of the new path candidate is updated.

### Effects of Second Embodiment

The second embodiment has been described above. In the present embodiment, the decoder 20 includes a processor which adds a plurality of branches depending on an information bit value to a path candidate, for information bits of indexes having a value not more than a predetermined index value, and adds likelihoods of the added branches to a likelihood of the path candidate. In contrast, for each path candidate, subsequent to an information bit next to an information bit corresponding to a value of a predetermined index value, the processor adds one branch from a plurality of added branches using hard decision to the path candidate. Therefore, for bits after an index having a value larger than the predetermined index, the number of path candidates does not increase, and the process of narrowing down the number of path candidates to the list number L in ascending order of PM can be omitted. Therefore, the decoder 20 reduces the time and amount of processing of the SCL decoding method.

### [c] Third Embodiment

The third embodiment is an example in which decoding is performed on the basis of a multibit SCL decoding method, by using a two-stage selection method. In the multibit SCL decoding method, by performing extension and selection of path candidates every predetermined number of bits M =2^{m} for estimation bit processing, on the basis of SCL decoding, processing time can be reduced.

Here, the definition of the multibit SCL decoding method will be described.

### [Definition]

1) multibit block (MB)

A multibit block represents a block for every M bits in the input order for an information bit-frozen bit sequence in an information bit estimation process.
2) MB symbol: b=b_{C}^{M-1}=(b₀, . . . , b_{M-1})

An MB symbol is a sequence of information frozen bits included in the MB. The MB symbol is simply expressed in vector form or binary form.
3) Types of MB symbols
(i) Information bit symbol: MB including at least one information bit. MB including bits all of which are information bits is called a “full information bit symbol”.
(ii) Frozen symbol: MB including bits all of which are frozen bits.
4) MB symbol number: Nₘ=N/M=2ⁿ/2^{m}=2^{n-m}

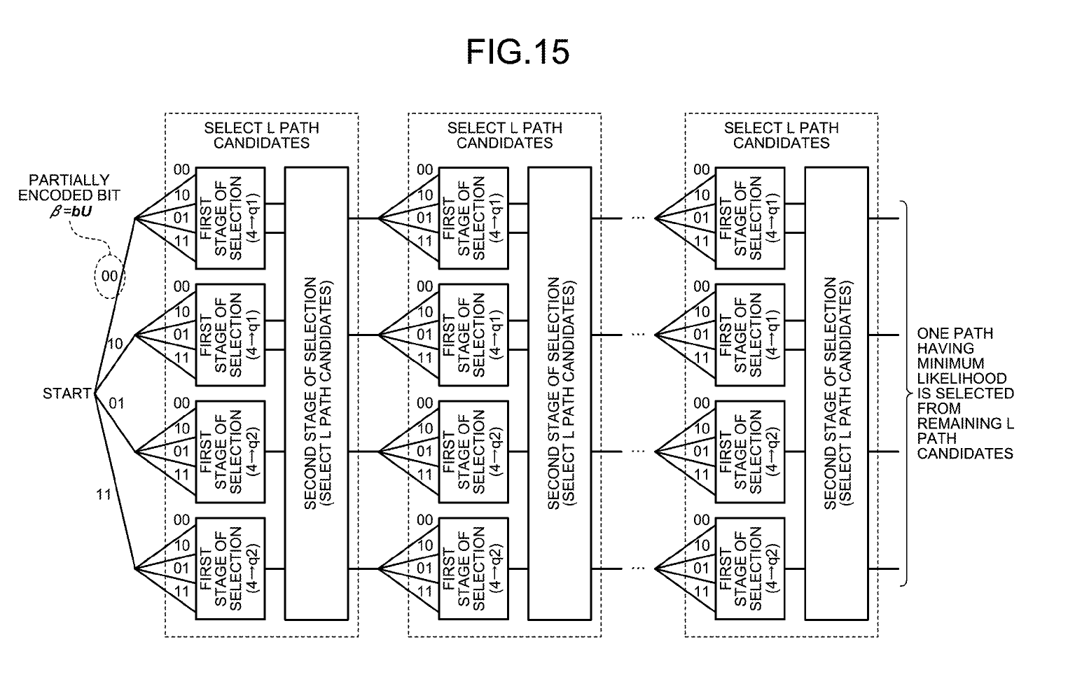

FIG. 15 is a diagram illustrating an example of a path candidate selection tree according to a third embodiment. In the example of FIG. 15, multibit number M=2 and list number L=4. In the multibit SCL decoding method, a block of M=2 bits, which is an index for distinguishing branches of a path, is not a bit included in an information-frozen bit sequence, but a partially encoded bit β=bU in which element encoding is performed by m=1 stage. For each M=2 bits, 2^{M}=4 branches are added to each path candidate in a list. Since 2^{M}=4 branches are added to each of L=4 paths every M=2 bits, 2^{M}×L=4×4=16 path candidates are sequentially generated as new path candidates, as a whole.

Then, the number of the generated path candidates are narrowed down to the list number L, on the basis of PMs of the respective path candidates. In the two-stage selection method, at the first stage of selection, from the 2^{M}=4 path candidates extended for each of L=4 path candidates in a current list, specified q path candidates are selected. Here, q<2^{M}. Finally, at the second stage of selection, L=4 path candidates are finally selected from a plurality of path candidates selected in the first stage.

In the two-stage selection method, the number of path candidates selected at each stage is smaller than 2^{M}×L=16, which is the total number of path candidates. Therefore, high-seed sorting of path candidates on the basis of the size of PM is achieved. Therefore, it is possible to reduce the time and amount of processing of the SCL decoding method.

Here, a path candidate including a branch having a small likelihood is likely to be selected as the final best path, but a path candidate including a branch having a large likelihood is unlikely to be selected as the final best path. Therefore, it is preferable to adjust the number of selections so that a branch having a small likelihood is selected from a plurality of branches at the first stage of selection. Therefore, when there are few branches having a small likelihood, the number of branches selected in the first stage is reduced, and high-speed selection can be achieved in the second stage.

The number of branches with a small likelihood may differ for each path candidate corresponding to a value of a partially encoded bit corresponding to an upper information bit. Therefore, in the present embodiment, a selection number q at the first stage is set to an independent value for each path candidate corresponding to a value of an upper partially encoded bit. In the example of FIG. 15, the selection number q in the first stage is set to q1=2 or q2=1 for each path candidate corresponding to the value of an upper partially encoded bit. The value of the selection number q in the first stage set to an independent value for each path candidate corresponding to the value of an upper partially encoded bit may be determined in advance on the basis of a result of the simulation or the like. A reference value of the selection number with respect to an index (for example, at least one of SNR, capacity, path metric, and average value of path metric) indicating the characteristics of each bit may be provided so that the selection number q is changed depending on a relationship between the reference value and the index. Therefore, it is possible to reduce the time and amount of processing of the multibit SCL decoding method by using the two-stage selection method.

Decoder 20

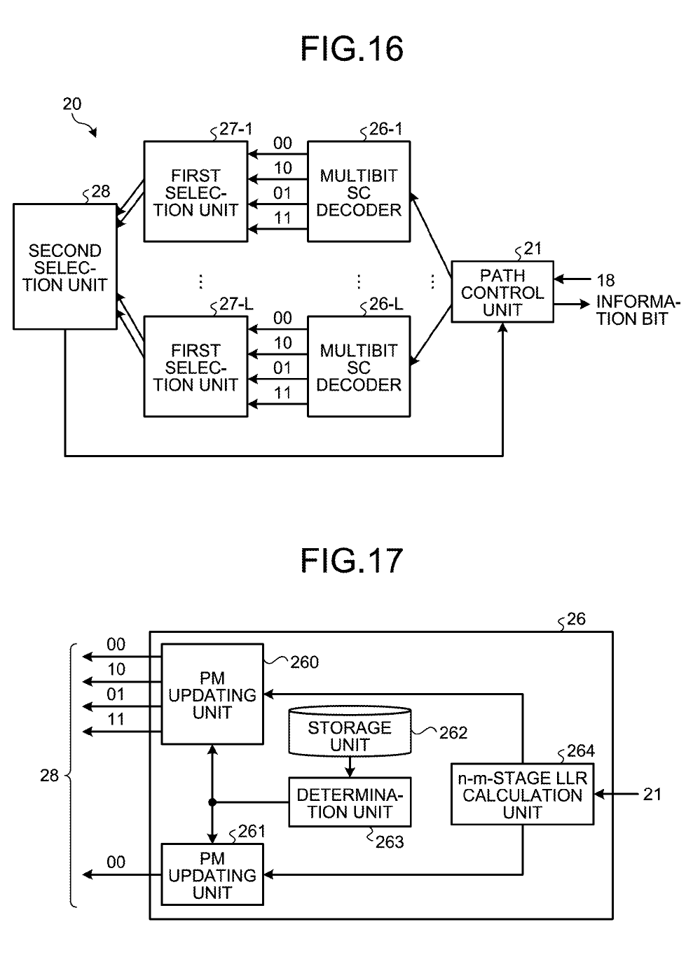

FIG. 16 is a diagram illustrating an example of a decoder 20 according to the third embodiment. The decoder 20 according to the present embodiment includes a path control unit 21 and a plurality of multibit SC decoders 26-1 to 26-L. Furthermore, the decoder 20 according to the present embodiment includes a plurality of first selection units 27-1 to 27-L and a second selection unit 28. In the following description, the plurality of multibit SC decoders 26-1 to 26-L are collectively called a multibit SC decoder 26 when the multibit SC decoders are not distinguished from each other, and the plurality of first selection units 27-1 to 27-27-L are collectively called a first selection unit 27 when the first selection units are not distinguished from each other. In addition, the decoder 20 is provided with a processor and a memory, and the processor executes a program read from the memory, whereby the function of each block illustrated in FIG. 16 is achieved.

The path control unit 21 outputs a channel LLR output from the demodulator 18 and path candidates selected by the second selection unit 28, to the multibit SC decoders 26. In the present embodiment, since the maximum L path candidates are selected, the path control unit 21 allocates path candidates selected by the second selection unit 28 to each of the L multibit SC decoders 26. Further, when path candidates for a partially encoded bit corresponding to the last bit of an information-frozen bit sequence are selected by the second selection unit 28, the path control unit 21 identifies a path candidate having the smallest PM from the selected path candidates. Then, the path control unit 21 performs error correction processing, such as CRC, on the information-frozen bit sequence identified from the partially encoded bit corresponding to the identified path candidate, and decodes an information bit. Then, the path control unit 21 outputs the decoded information bit.

Each multibit SC decoder 26 calculates an LLR of each added branch, for each path candidate. Then, each multibit SC decoder 26 updates path candidates and PMs thereof by adding an LLR calculated for each branch to a PM of a path candidate.

Each of the first selection units 27 receives path candidates for which the PMs are updated by the multibit SC decoder 26, and performs the first stage of selection of the two-stage selection method from among the received path candidates. That is, qₖ path candidates are selected from newly generated 2^{M} path candidates in ascending order of PM, for each of L-th path candidates of k=1, . . . . The number qₖ of path candidates selected by the respective first selection units 27 is set to an independent value for each of the first selection units 27 in advance. Then, each first selection unit 27 outputs the selected qₖ path candidates and PMs thereof to the second selection unit 28. For example, a total number Q of path candidates input to the second selection unit 28 is expressed as follows.

$$Q = {\sum }_{k = 1}^{L} {q}_{k}$$

When the total number Q of path candidates output from the respective first selection units 27 is less than or equal to a preset list number L, the second selection unit 28 outputs the path candidates and PMs thereof output from the respective first selection units 27 to the path control unit 21. In contrast, when the total number Q of path candidates output from the respective first selection unit 27 is larger than the list number L, the second selection unit 28 selects path candidates, the number of which is equal to the list number L, in ascending order of PM value. Then, the second selection unit 28 outputs the selected path candidates and PMs thereof to the path control unit 21.

Multibit SC Decoder 26

FIG. 17 is a block diagram illustrating an example of each multibit SC decoder 26 according to the third embodiment. The multibit SC decoder 26 according to the present embodiment includes a PM updating unit 260, a PM updating unit 261, a storage unit 262, a determination unit 263, and an n-m stage LLR calculation unit 264. The n-m stage LLR calculation unit 264 calculates an LLR of each branch at each n-m stage and outputs the calculated LLR to the PM updating unit 260 and the PM updating unit 261. In the following description, a process of calculating an LLR of each branch in each stage may be referred to as n-m stage LLR operation.

The storage unit 262 stores an index value of a frozen bit in an information-frozen bit sequence. The storage unit 262 may store an index value of an information bit. The determination unit 263 refers to the storage unit 262 for each index value and determines whether the index value represents an index of an information bit symbol or an index of a frozen symbol. Then, the determination unit 263 outputs a determination result to the PM updating unit 260 and the PM updating unit 261.

When it is determined that the index is an index of an information bit symbol by the determination unit 263, the PM updating unit 260 adds, to a path candidate corresponding to a partially encoded bit corresponding to an upper information bit, a plurality of branches corresponding to a partially encoded bit corresponding to a lower information bit (branches corresponding to “00”, “10”, “01”, and “11” in the example of FIG. 15). Then, for each of the added branches, the PM updating unit 260 sets a path candidate to which each of the branches is added, as a new path candidate. Then, the PM updating unit 260 adds an LLR of a branch calculated by the n-m stage LLR calculation unit 264 to a PM of a path candidate, thereby updating a PM of the new path candidate. Then, the PM updating unit 260 outputs the new path candidate and the updated PM thereof to the second selection unit 28.

When it is determined that the index is an index of a frozen symbol by the determination unit 263, the PM updating unit 261 adds a branch corresponding to “00” which is a value of the frozen symbol to the path candidates. Then, the PM updating unit 261 sets a path candidate to which the branch is added as a new path candidate. Then, the PM updating unit 261 adds an LLR of a branch calculated by the n-m stage LLR calculation unit 264 to a PM of a path candidate, thereby updating a PM of the new path candidate. Then, the PM updating unit 261 outputs the new path candidate and the updated PM thereof to the second selection unit 28.

Operation of Decoder 20

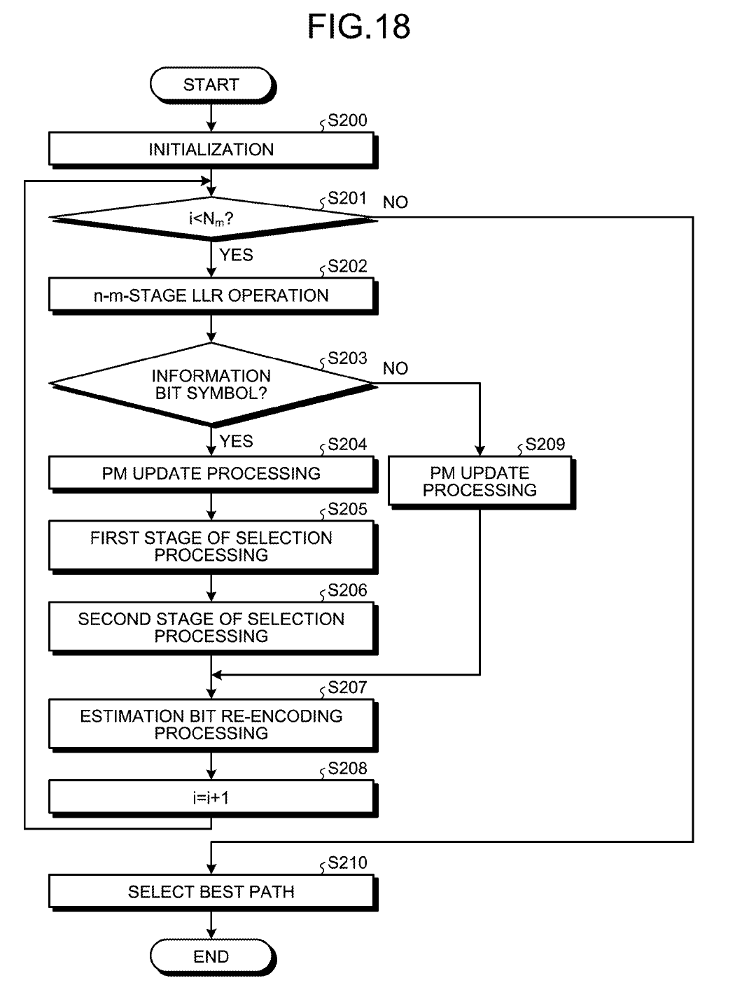

FIG. 18 is a flowchart illustrating an example of the operation of the decoder 20 according to the third embodiment. The decoder 20 starts operation of this flowchart, for example, each time a code of predetermined length N is received.

First, the decoder 20 initializes each part (S200). In Step S200, for example, the value of variable i indicating the index of an information-frozen bit sequence is initialized to zero.

Next, the path control unit 21 determines whether the value of the variable i is less than an MB symbol number Nₘ (S201). When the value of the variable i is less than the value of Nₘ (S201: Yes), the n-m stage LLR calculation unit 264 in each multibit SC decoder 26 executes n-m stage LLR operation (S202). Then, the determination unit 263 refers to the storage unit 262 and determines whether the MB symbol having an index corresponding to the variable i is an information bit symbol (S203). When the MB symbol having an index corresponding to the variable i is the information bit symbol (S203: Yes), the PM updating unit 260 adds a plurality of branches to a path candidate, and sets the path candidate to which the branches are added as a new path candidate, for each of the added branches. Then, the PM updating unit 260 adds an LLR of a branch calculated by the n-m stage LLR calculation unit 264 to a PM of a path candidate, thereby updating a PM of the new path candidate (S204).

Next, each of the first selection units 27 performs the first stage of selection processing to select path candidates, the number of which is equal to the selection number q, from path candidates output from the multibit SC decoder 26, in ascending order of PM values (S205). Since the selection number q is set to an independent value for each first selection unit 27 in advance, the selection number q can differ between the first selection units 27.

Next, the second selection unit 28 performs the second stage of selection processing to select the maximum L path candidates from path candidates output from each of the first selection units 27, in ascending order of PM values (S206). Then, the path control unit 21 executes re-encoding processing of an estimation bit on the basis of the path candidates selected by the second selection unit 28 (S207). Then, the path control unit 21 increases the variable i by 1 (S208) and performs the processing of Step S201 again.

In Step S203, when the MB bit symbol having an index corresponding to the variable i is a frozen symbol (S203: No), the PM updating unit 261 adds a branch corresponding to “00” which is the value of the frozen symbol to the path candidate. Then, the PM updating unit 261 sets a path candidate to which the branch is added as a new path candidate. Then, the PM updating unit 261 adds an LLR of the branch of a frozen symbol calculated by the n-m stage LLR calculation unit 264 to a PM of the path candidate, thereby updating a PM of the new path candidate (S209). Then, the processing of Step S207 is performed.

In Step S201, when the value of the variable i is not less than the value N of Nₘ (S201: No), the path control unit 21 selects a path candidate having the smallest PM from the path candidates selected by the second selection unit 28 to select the best path (S210). The path control unit 21 performs error correction processing, such as CRC, on the information-frozen bit sequence identified from the partially encoded bit corresponding to the selected path candidate, and decodes an information bit. Then, the path control unit 21 outputs the decoded information bit.

### Effects of Third Embodiment

The third embodiment has been described above. In the present embodiment, a processor of the decoder 20 is a decoder for decoding an information bit sequence from a code sequence encoded by the polar code by using an SCL decoding method, and the decoder 20 includes the processor and a memory connected to the processor. The processor sets, to independent values, the value of the selection number q for limiting the number of path candidates to sequentially identify candidates for an information bit sequence, for each branch of an upper information bit to which a plurality of branches in a lower information bit is added. Therefore, the decoder 20 reduces the time and amount of processing of the SCL decoding method.

Furthermore, in the present embodiment, the processor of the decoder 20 performs a multibit successive cancellation list decoding method which is a method of selecting path candidates at two stages to set the value of selection number q of branches selected in the first stage, to an independent value for each path candidate corresponding to a value of an upper information bit. In the first stage, the branches are selected from a plurality of branches added to a branch corresponding to a value of an upper information bit included in an information bit sequence.

### [d] Fourth Embodiment

The fourth embodiment is an example of further increasing the speed of the first stage of selection processing according to the third embodiment. The present fourth embodiment is different from the third embodiment in the first-stage selection method of the multibit SCL decoding method using the two-stage selection method. Hereinafter, differences from the third embodiment will be mainly described.

In the present embodiment, when a hard decision bit of a log likelihood ratio αᵢ of each bit is different from a re-encoded bit β=bU of an MB symbol, the total of additional likelihood amount is determined by adding |αᵢ| as a penalty amount. An MB symbol is represented by b, and a generator matrix U is expressed as follows.

U=F^{\textcircled{×}m}

The additional likelihood amount is obtained by, for example, min-sum approximation, but a method of calculating the additional likelihood amount is not limited to the min-sum approximation.

In the present embodiment, dimensional order of the selection processing is determined to some extent before the selection processing is performed. In particular, when there is no penalty, a likelihood Lᵢ is the smallest and Lᵢ=0. In contrast, when only one bit differs between the hard decision and a re-encoded bit (hereinafter referred to as “mismatch bit”), Lᵢ=|αᵢ|, and the likelihood Lᵢ may be smaller than that when two or more mismatched bits are included.

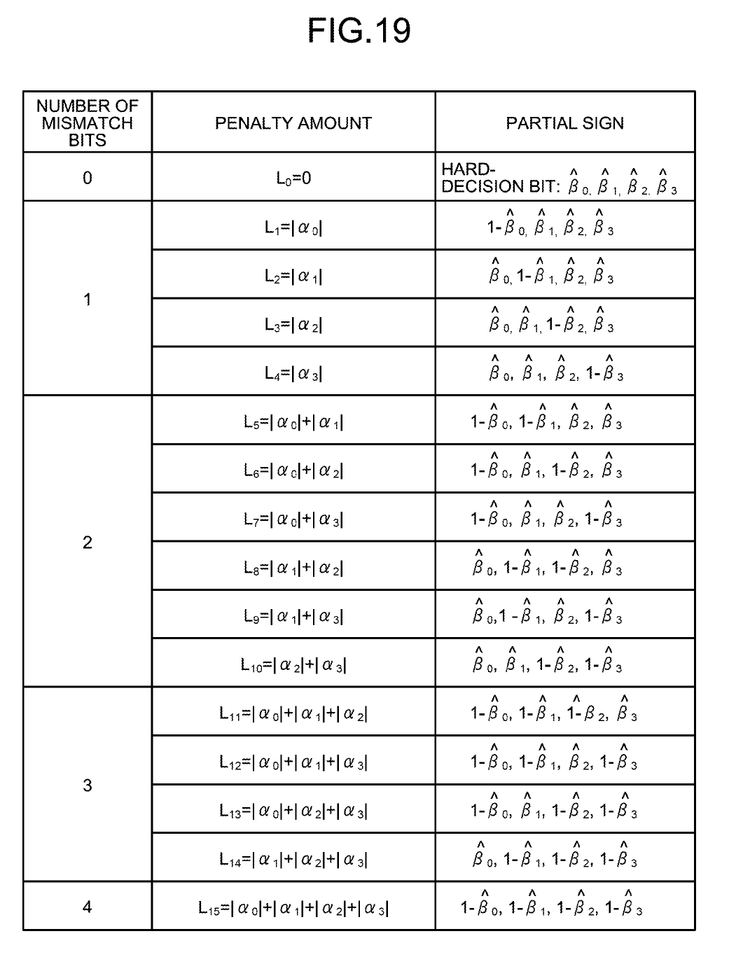

FIG. 19 is a diagram illustrating an example of a penalty table according to the fourth embodiment. Penalty amounts illustrated in FIG. 19 are exemplified as the additional likelihood amounts corresponding to mismatch bits. Furthermore, the additional likelihood is an example of an offset of the likelihood. In the present embodiment, for example, selection of a path candidate is performed where the number of different bits is not more than one. In the present embodiment, for example, selection number qₖ=M+1=5. Incidentally, when the value of the selection number qₖ is increased, the possibility of selection of the best path is increased, and the characteristics are improved.

The configurations of a decoder 20 and each multibit SC decoder 26 according to the present embodiment are the same as the configurations of the decoder 20 and each multibit SC decoder 26 according to the third embodiment which are described with reference to FIGS. 16 and 17. Further, the penalty table illustrated in FIG. 19 is stored, for example, in a storage unit 262 in each multibit SC decoder 26.

Operation of Decoder 20

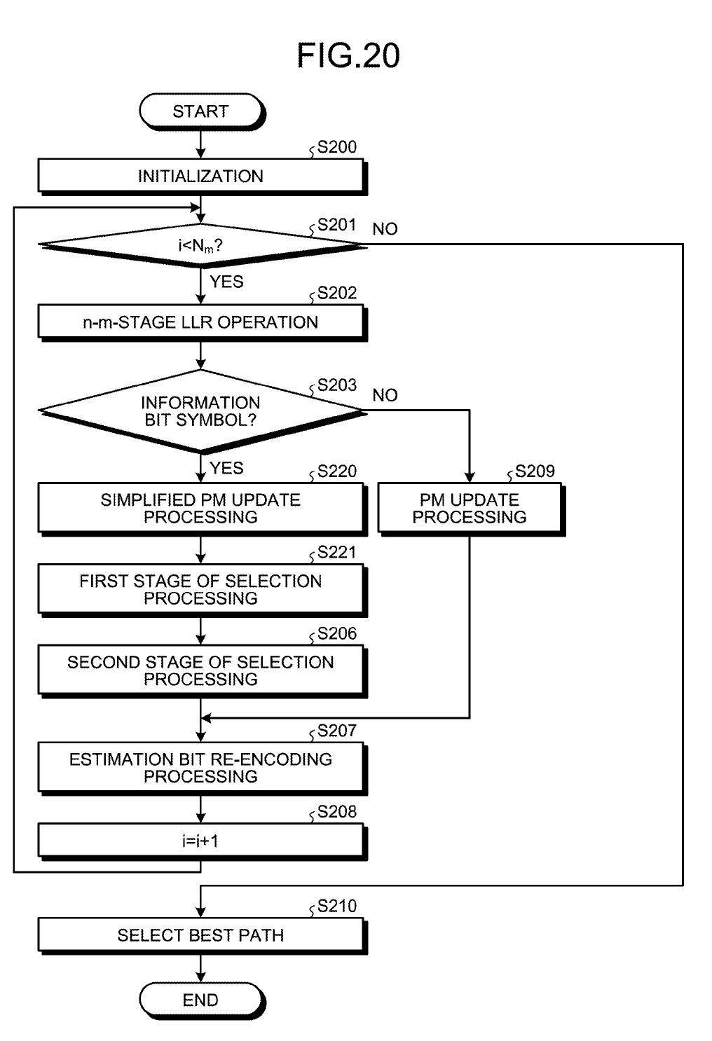

FIG. 20 is a flowchart illustrating an example of the operation of the decoder 20 according to the fourth embodiment. Note that in FIG. 20, processing denoted by the same reference numerals as those of the processing illustrated in FIG. 18 is the same as the processing illustrated in FIG. 18, except for the points described below, and duplicate explanations are omitted.

In Step S203, when an MB symbol having an index corresponding to a variable i is an information bit symbol (S203: Yes), the multibit SC decoder 26 performs simple PM update processing (S220). In Step S220, an n-m stage LLR calculation unit 264 compares a re-encoded bit of the MB symbol with a hard decision bit of a log likelihood ratio a, of each bit, and identifies a mismatch bit. The n-m stage LLR calculation unit 264 refers to a penalty table in the storage unit 262 to acquire a penalty amount corresponding to the identified mismatch bit and outputs the acquired penalty amount to a PM updating unit 260 and a PM updating unit 261. The PM updating unit 260 adds a plurality of branches to a path candidate and sets the path candidate to which the branches are added as a new path candidate, for each added branch. Then, the PM updating unit 260 adds a penalty amount output from the n-m stage LLR calculation unit 264 to a PM of a path candidate, thereby updating a PM of the new path candidate.

Next, each of first selection units 27 performs the first stage of selection processing to select path candidates, the number of which is equal to the selection number q, from path candidates output from the multibit SC decoder 26, in ascending order of PM values (S221). For example, when the selection number q_{k is M+}1=5, in Step S221, each first selection unit 27 selects a path candidate, for example, having a penalty amount of not more than one which is added by the multibit SC decoder 26. Therefore, the first selection unit 27 according to the present embodiment can omit processing of comparing the values of a plurality of PMs. Therefore, the first-stage of selection processing is simplified and the first stage of selection processing is performed at high speed.

### Effects of Fourth Embodiment

The fourth embodiment has been described above. In the present embodiment, a processor of the decoder 20 performs a multibit successive cancellation list decoding method which is a method of selecting path candidates at two stages to apply an additional likelihood amount depending on the number of bits not matching between a re-encoded partially encoded bit and a partially encoded bit obtained by a hard decision bit, to each of a plurality of branches added to a branch corresponding to a value of an upper information bit included in an information bit sequence. Then, in the first stage of selection, the decoder 20 selects a predetermined number of branches in ascending order of applied additional likelihood amount. Therefore, the decoder 20 reduces the time and amount of processing of the SCL decoding method.

In addition, in the present embodiment, the processor of the decoder 20 specifies an additional likelihood amount for each of a plurality of branches added to a branch corresponding to a value of an upper information bit included in an information bit sequence. Then, the processor of the decoder 20 adds the specified additional likelihood amount to a likelihood of a path candidate including a branch corresponding to an upper information bit. Therefore, the decoder 20 reduces the time and amount of processing of the SCL decoding method.

Hardware

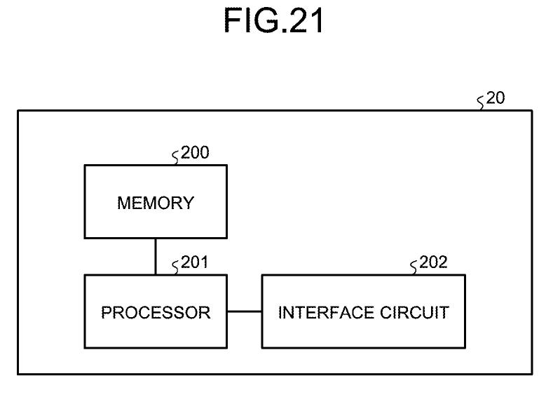

For example, the decoder 20 in each of the first to fourth embodiments described above is implemented by hardware as illustrated in FIG. 21. FIG. 21 is a diagram illustrating an example of hardware of the decoder 20. For example, as illustrated in FIG. 21, the decoder 20 has a memory 200, a processor 201, and an interface circuit 202.

The interface circuit 202 is an interface for performing wired communication with another device such as the demodulator 18. The memory 200 stores, for example, various programs for implementing the functions of the decoder 20. The processor 201 implements the functions of the decoder 20 by executing programs read from the memory 200.

For example, in the decoder 20 according to the first embodiment, programs for implementing the functions of the path control unit 21, the plurality of SC decoders 22, the selection unit 23, and the list number switching unit 24 are stored in the memory 200. By executing a program read out from the memory 200, the memory 200 implements the functions of the path control unit 21, the plurality of SC decoders 22, the selection unit 23, and the list number switching unit 24.

Further, for example, in the decoder 20 according to the second embodiment, programs for implementing the functions of the path control unit 21, the plurality of SC decoders 22, the selection unit 23, and the hard-decision instruction unit 25 are stored in the memory 200. The memory 200 implements the functions of the path control unit 21, the plurality of SC decoders 22, the selection unit 23, and the hard-decision instruction unit 25 by executing programs read from the memory 200.

Furthermore, for example, in the decoder 20 according to the third or fourth embodiment, programs for implementing the functions of the path control unit 21, the plurality of multibit SC decoders 26, the plurality of first selection units 27, and the second selection unit 28 are stored in the memory 200. By executing a program read from the memory 200, the memory 200 implements the functions of the path control unit 21, the plurality of multibit SC decoders 26, the plurality of first selection units 27, and the second selection unit 28.

Note that programs, data, and the like in the memory 200 are not necessarily entirely stored in the memory 200 from the beginning. For example, programs, data, or the like may be stored in a portable recording medium, such as a memory card inserted in the reception device 16 so that the decoder 20 acquires each program, data, or the like from such a portable recording medium for implementation thereof. Further, from another computer or server device that stores programs, data, or the like, the decoder 20 may acquire each program via a wireless communication line, a public line, the Internet, a LAN, a WAN, or the like for implementation thereof.

Others

It is to be understood that the disclosed technology is not limited to the above embodiments, and various modifications may be made within the scope of the invention.

For example, in the above-described third embodiment, the selection number qₖ is set to an independent value for each branch of an upper information bit to which a plurality of branches in a lower information bit is added, but the disclosed technology is not limited thereto. For example, the selection number qₖ may be set to an identical number for each branch of an upper information bit to which a plurality of branches in a lower information bit is added, or may be set to an independent value for each position of an information bit in an information bit sequence. In particular, the selection number qₖ may be configured so that the value of selection number set in a block including an information bit having a larger index value is set to a smaller value than a value of selection number set in a block including an information bit having a smaller index value.

In each of the above-described embodiments, processing blocks of the decoder 20 are divided into functions according to main processing contents for ease of understanding each device in each embodiment. Therefore, the disclosed technology is not limited by the method of dividing processing blocks or the name of the method. Further, each processing block of the decoder 20 in each of the above-described embodiments may be divided into fine processing blocks according to the processing contents, or a plurality of processing blocks may be integrated into one processing block. In addition, the processing executed by each processing block may be implemented as processing executed by software or may be implemented by dedicated hardware such as application specific integrated circuit (ASIC).

According to one aspect of a decoder, a decoding method, and a communication system disclosed in the present application, the time and amount of processing of an SCL decoding method can be effectively reduced.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A decoder for decoding an information bit sequence from a code sequence encoded by a polar code by using a successive cancellation list decoding method, the decoder comprising:
a processor; and
a memory connected to the processor,
wherein the processor executes a process comprising:
configuring a value of a parameter that limits number of path candidates to sequentially identify candidates for the information bit sequence, to an independent value, for each position of an information bit in the information bit sequence or for each branch of an upper information bit to which a plurality of branches in a lower information bit is added.

2. The decoder according to claim 1, wherein the processor further executes a process comprising
estimating the information bit sequence based on one path candidate in specified path candidates.

3. The decoder according to claim 1, wherein
the configuring includes dividing the information bit sequence into a plurality of blocks including at least one information bit, and configuring a value of a parameter that limits the number of path candidates to sequentially identify candidates for the information bit sequence to an independent value for each of the blocks.

4. The decoder according to claim 3, wherein
the configuring includes configuring, in the information bit sequence, a value of the parameter set to a block including an information bit having a larger index value, to a value smaller than a value of the parameter set to a block including an information bit having a smaller index value, the index indicating a position of an information bit in the information bit sequence.

5. The decoder according to claim 3, wherein
the configuring includes configuring, in a multibit successive cancellation list decoding method being a method of selecting a path candidate in two stages, a value of selection number for branches selected in the first stage from a plurality of branches added to a branch corresponding to a value of an upper information bit included in the information bit sequence, in order for a value of the selection number set to a block including an information bit having a larger index value to be set to a value smaller than a value of the selection number set to a block including an information bit having a smaller index value in the information bit sequence, the index value indicating a position of an information bit in the information bit sequence.

6. The decoder according to claim 1, wherein
the process further comprising:
adding a plurality of branches depending on a value of an information bit to path candidates , and adding a likelihood of each added branch to a likelihood of a path candidate, up to an information bit corresponding to a predetermined index value, and
adding one branch from a plurality of added branches by using a hard decision to a path candidate, for each path candidate, subsequent to an information bit next to an information bit corresponding to a value of a predetermined index value.

7. The decoder according to claim 1, wherein
the configuring includes configuring, in a multibit successive cancellation list decoding method being a method of selecting a path candidate in two stages, a value of selection number for branches selected in the first stage from a plurality of branches added to a branch corresponding to a value of the upper information bit included in the information bit sequence, to an independent value for each path candidate corresponding to a value of the upper information bit.

8. The decoder according to claim 1, wherein
the configuring includes applying, in a multibit successive cancellation list decoding method being a method of selecting a path candidate in two stages, an additional likelihood amount to each of a plurality of branches added to a branch corresponding to a value of the upper information bit included in the information bit sequence, depending on number of bits not matching between a re-encoded partially encoded bit and a partially encoded bit obtained by a hard decision bit, and
selecting a predetermined number of branches in ascending order of applied additional likelihood amounts, in the first stage of selection.

9. The decoder according to claim 1, wherein a parameter that limits the path candidates varies depending on an index indicating a characteristic of each bit.

10. A decoding method, the method performed by a decoder including a processor and a memory connected to the processor to decode an information bit sequence by using a successive cancellation list decoding method, from a code sequence encoded by a polar code, the method comprising:
configuring a value of a parameter that limits number of path candidates to sequentially identify candidates of the information bit sequence, for each position of information bit in the information bit sequence or for each branch of the upper information bit to which a plurality of branches in the lower information bit is added to an independent value, by using the processor; and
estimating the information bit sequence based on one path candidate in specified path candidates, by using the processor.

11. A communication system comprising:
a transmission device that transmits a code sequence having an information bit sequence coded by a polar code; and
a reception device that decodes an information bit sequence by using a successive cancellation list decoding method from a signal transmitted from the transmission device
wherein the reception device includes:
a decoder includes a processor and a memory connected to the processor
the processor executes a process comprising:
configuring a value of a parameter that limits number of path candidates to sequentially identify candidates for the information bit sequence, to an independent value, for each position of an information bit in the information bit sequence or for each branch of an upper information bit to which a plurality of branches in a lower information bit is added; and
estimating the information bit sequence based on one path candidate in specified path candidates.
